(19) United States
(12) Patent Application Publication
(10) Pub. No.: US 2025/0311178 A1
(43) Pub. Date: Oct. 2, 2025

(54) ELECTRICAL COMPONENT

(71) Applicant: HONDA MOTOR CO., LTD., Tokyo (JP)

(72) Inventor: Takanori SAKAGUCHI, Wako-shi (JP)

(21) Appl. No.: 19/063,787

(22) Filed: Feb. 26, 2025

(30) Foreign Application Priority Data
Mar. 28, 2024 (JP) 2024-052866

(51) Int. Cl. H05K 7/20; B60L 50/70; H05K 7/14

(52) U.S. Cl. CPC H05K 7/20927; H05K 7/1407; B60L 50/70

(57) ABSTRACT

An electrical component preventing leakage of cooling liquid and allowing anti-vibration includes: an electrical component body housing an electrical element and including a first through-hole for fixing; a plate provided with a second through-hole facing the first through-hole and a cooling hole through which cooling liquid flows; anti-vibration rubbers arranged on one side and other side of the plate while surrounding the second through-hole of the plate and each having a third through-hole facing the second through-hole, and gaskets arranged twice or more times surrounding the cooling hole respectively on the one side and the other side of the plate, wherein the electrical component body, the plate, the anti-vibration rubbers, and the gasket are fixed to a housing, and the electrical component body has a bottom surface at least a portion of which is contact with the cooling liquid flowing through a cooling liquid channel of the housing.

### REFERENCE TO RELATED APPLICATIONS

The present invention relates to and asserts priority from Japanese patent application No. 2024-052866 filed on Mar. 28, 2024, and incorporates the entirety of the contents and subject matter of all the above application herein by reference.

### TECHNICAL FIELD

This invention relates to electrical component.

### BACKGROUND ART

Conventionally, the following structures may be used to cool heat-generating electrical elements such as capacitors, reactors, and the like.

The heat-generating electrical element is molded with resin to form a molded resin product (hereinafter referred to as “molded product”). A part of the molded product is in contact with cooling liquid, and there is a connection part of components with each other at a point of the contact with the cooling liquid. The connection part is provided with a sealing member to suppress leakage of the cooling liquid. For example, Patent Literature 1 (PTL 1) describes a configuration shown in FIG. 8 below, which shows an enlarged cross-sectional view of a conventional cooling structure for electrical component.

Because an electrical elements 101 such as capacitor and reactor generates heat while operation, an electrical component body 101 of the molded product is cooled by contacting and exchanging heat with cooling liquid 109 flowing through the cooling liquid channel 102s formed in the housing 102.

The cylindrical anti-vibration member 103, which is placed between the electrical component body 101 and the housing 102, has a cylindrical anti-vibration rubber 103r fixed in a center thereof. The anti-vibration rubber 103r dampens vibration of the housing 102.

The electrical component body 101 with a sealing structure is secured to the housing 102 by a bolt 104 that is inserted through the electrical component body 101 and the anti-vibration member 103 to be screwed into the housing 102.

Between the housing 102 and the electrical component body 101 is a seal member 105 having a double seal structure (roughly H-shaped cross-sectional structure) with seals 105a and 105b that suppress leakage of the cooling liquid 109. The housing 102 has seal member buckling prevention walls 102a and 102b formed on both sides of the seal member 105 to sandwich the seal member 105 for preventing it from collapse.

### CITATION LIST

### Patent Literature

PTL 1: Japanese Patent No. 6046812

### SUMMARY OF INVENTION

### Technical Problem

However, the conventional technology of PTL 1 assumes a structure of a flange connection of piping. Such technology does not consider problems that may arise when cooling the electrical component body 101 by directly contacting it to the cooling liquid 109 in the cooling liquid channel 102s, which problem include molding of the cooling liquid channel 102s of the housing 102 in which the electrical component body 101 is mounted, anti-vibration effect of the housing 102 against vibration, flow pressure of the cooling liquid applied on the electrical component body 101, and the like.

As shown in FIG. 8, when the sealing member 105 for waterproofing and the anti-vibration member 103 for the anti-vibration are simply lined up, a dimension from the cooling liquid channel 102s to a fixing part using a bolt 104 is long.

For example, the waterproofing function requires a length of s1 for the seal member buckling prevention wall 102a, a length of s2 for the seal member buckling prevention wall 102b, and a groove width of s3 for the seal member 105.

The anti-vibration requires an assembly dimension of s4 for the seal member 105. Because a clearance is required between the seal member buckling prevention wall 102b and the anti-vibration member 103, the waterproof and anti-vibration functions require the overall dimension of s1+s2+s3+s5.

In addition, because the seal member 105 that is a component for the waterproofing and the anti-vibration member 103 that is a component for anti-vibration are separate parts, there are problems that many man-hours are required and a large variation in dimensions might occur when assembling them into the housing 102.

The present invention is devised in view of the above-described background, and a purpose of the present invention is to provide an electrical component that can suppress leakage of cooling liquid and also provides anti-vibration.

### Solution to Problem

To solve the above problem, an electrical component of the present invention includes: an electrical component body that houses therein an electrical element and has a bottom surface at least a part of which forms a flat shape and a first through-hole for fixing provided on a part of the flat shape; a plate that is provided with a second through-hole facing the first through-hole and a cooling hole through which cooling liquid flows; anti-vibration rubbers arranged on one side and other side of the plate while surrounding the second through-hole of the plate and each having a third through-hole; and gaskets arranged respectively on the one side and the other side of the plate while surrounding the cooling hole twice or more, wherein the electrical component body, the plate, and the anti-vibration rubber, and the gasket are fixed to a housing, and wherein the electrical component body has a bottom surface at least a part of which is contact with the cooling liquid flowing through a cooling liquid channel of the housing.

### Effects of Embodiments

The embodiments of the present invention provide an electrical component that is able to suppress leakage of cooling liquid and vibration.

### BRIEF DESCRIPTION OF DRAWINGS

FIG. 1 is a conceptual perspective view of a vehicle of a first embodiment.

FIG. 2 is a perspective view of a VCU (Voltage Control Unit) case.

FIG. 3 is a partially enlarged cross-sectional view of a main part of a cooling and anti-vibration structure in the VCU.

FIG. 4A is a top view of a cooling liquid leakage prevention and anti-vibration component.

FIG. 4B is a I-I cross sectional view of FIG. 4A.

FIG. 5A is top view of a support plate.

FIG. 5B is a exploded side view of an anti-vibration rubber.

FIG. 6A is a view of a cooling liquid leakage prevention and anti-vibration component viewed from one side according to a second embodiment.

FIG. 6B is a partially enlarged view of a II-II cross-section of FIG. 6A.

FIG. 7 is a partially enlarged view of the II-II cross-section of FIG. 6A showing a process of assembling the cooling liquid leakage prevention and anti-vibration components.

FIG. 8 is a partially enlarged cross-sectional view of a conventional cooling structure for an electrical component.

### DESCRIPTION OF EMBODIMENTS

### First Embodiment

Hereinbelow, detailed description is given of an embodiment of the present invention with reference to the drawings as appropriate.

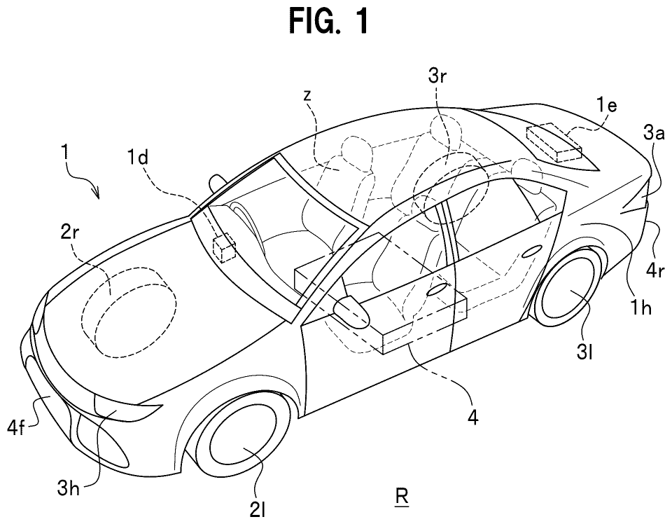

FIG. 1 is a conceptual perspective view of a vehicle 1 according to the first embodiment.

The vehicle 1 of the embodiment is, for example, a vehicle powered by a fuel cell or storage battery, i.e., a fuel cell vehicle (FCV), an electric vehicle (BEV), further a hybrid vehicle (HEV). The fuel cell vehicle is a vehicle that runs by turning a motor using electric energy generated by transfer between electrodes of H+ (cation) and O−2 (anion) produced by chemical reaction between hydrogen and oxygen.

The vehicle 1 is provided at its front side with right front wheels 2r and left front wheels 2l, which are steering wheels that change a travelling direction of the vehicle 1. The vehicle 1 is provided at its rear side with right rear wheels 3r and left rear wheels 3l, which are driven wheels or driving wheels.

The vehicle 1 is provided at its front with headlights 3h that illuminate front of a road surface R, and at its rear with rear lights 3a to illuminate rearward of the road surface R. Further, there are a front bumper 4f and a rear bumper 4r that absorb impact respectively of front and rear collisions respectively at the front and rear of the vehicle 1.

The vehicle 1 is controlled by a control unit (ECU) 1e. Rotation of a vehicle body 1h is detected by a yaw rate sensor (not shown), and a steering angle of the vehicle body 1h is detected by a steering angle sensor 1d.

Shafts and other rotating parts of the right front wheels 2r and left front wheels 2l are respectively equipped with wheel speed sensors (not shown) to detect rotational speeds of the right front wheels 2r and the left front wheels 2l.

Information (sensor currents) detected from each of the yaw rate sensor, steering angle sensor 1d, and each of the wheel speed sensors is inputted to the control unit 1e.

A fuel cell (not shown) is placed on an under panel in the body below a seat z of the vehicle 1.

There is placed just above the fuel cell a VCU (Voltage Control Unit) 4 that works for converting electric power of the fuel cell to a desired voltage.

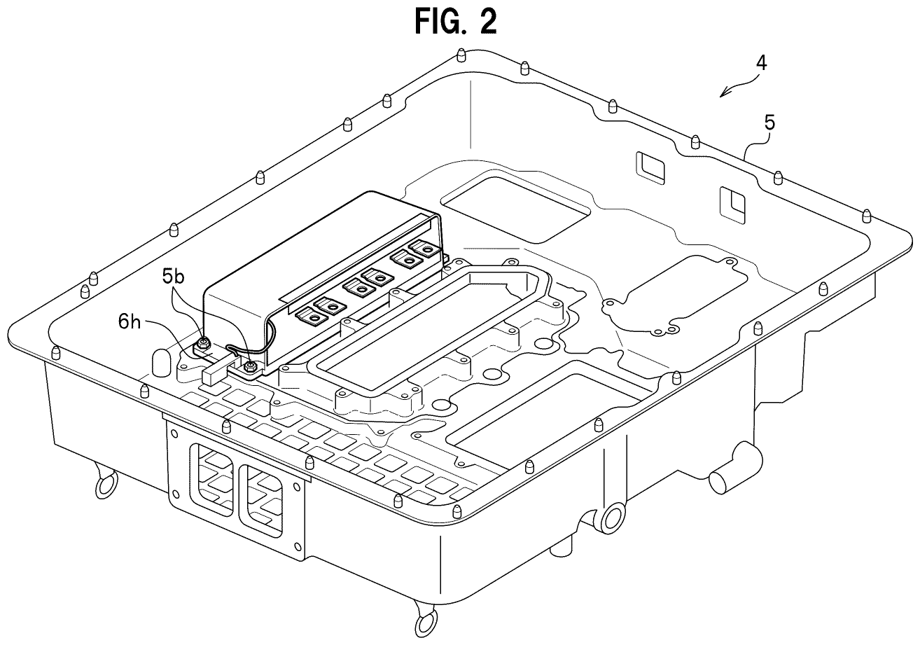

The VCU 4 has an outer shell formed by a bottomed box-shaped VCU case (housing) 5 whose top is open as shown in FIG. 2. FIG. 2 is a perspective view of the VCU case 5.

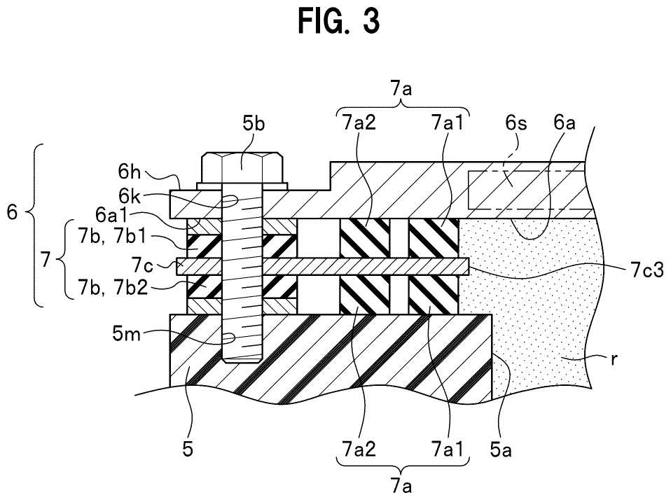

FIG. 3 is a partially enlarged cross-sectional view showing a main part of a cooling and anti-vibration structure in the VCU 4.

### <VCU Case (Housing) 5>

Inside the VCU case 5, there are mounted electrical elements 6s such as capacitors, reactors, power semiconductors, and the like, which generate heat due to ripple current, Joule heat, switching loss, and the like. The electrical elements 6s are resin-molded and resin-sealed electrical component body 6h in FIG. 3.

To cool the electrical component body 6h in which the electric element 6s is encapsulated, cooling liquid r (see FIG. 3) flowing through a cooling liquid channel 5a is brought into direct contact with the electrical component body 6h.

The purpose of the present invention is to improve a function of preventing cooling liquid r from leaking outside, isolation of vibration that is transferred from the VCU case 5 fixed to the vehicle 1 to the electrical component body 6h, and assembly workability around the electrical component body 6h.

That is, the VCU case 5 is equipped with a structure (cooling liquid channel 5a and cooling liquid r) to cool the electrical component body 6h in which the heat-generating electric elements 6s are encapsulated.

Furthermore, the electrical component 6 (see FIG. 3) has an anti-vibration structure that suppresses vibrations that are transferred from the VCU case 5, which is fixed to the vehicle body 1h (see FIG. 1), to the electrical component body 6h.

The electrical component 6 shown in FIG. 3 includes an electrical component body 6h and a liquid leakage prevention and anti-vibration component 7 that has the function of preventing cooling liquid r from leaking to outside (double sealing gasket 7a) and an anti-vibration structure (anti-vibration rubber 7b).

### <Cooling and Anti-vibration Structure of Electrical Component 6>

Hereinbelow, detailed description is given of the cooling and anti-vibration structure included by the electrical component 6.

The VCU case 5 shown in FIG. 3 includes a cooling liquid channel 5a, through which the cooling liquid r flows to cool the heat-generating electrical component body 6h. The cooling liquid is heated to be hot through heat exchange with the electrical component body 6h and cooled by heat exchange with external air in a radiator (not shown).

As mentioned above, the electrical component body 6h is a molded product in which the electric elements 6s are encapsulated, and sealed with resin at least a portion (bottom of the electrical component body) 6a (see FIG. 3) with which the cooling liquid r comes into contact. The electric elements 6s are assumed to include electronic elements.

The electrical component body 6h shown in FIG. 3 that houses the electric element 6s includes a portion 6a1 whose surface forms at least partially a flat shape in the bottom 6a. And the first through-hole 6k for fixing is formed in the portion 6a1 forming the flat shape in the electrical component body 6h.

There is fixed the liquid leakage prevention and anti-vibration component 7 between the VCU case 5 and the main body of the electrical component body 6h, which are shown in FIG. 3, by a bolt 5b being screwed into a female thread 5m of the VCU case 5. As mentioned above, the combination of the electrical component body 6h and the liquid leakage prevention and anti-vibration component 7 together is called the electrical component 6.

### <Liquid Leakage Prevention and Anti-Vibration Component 7>

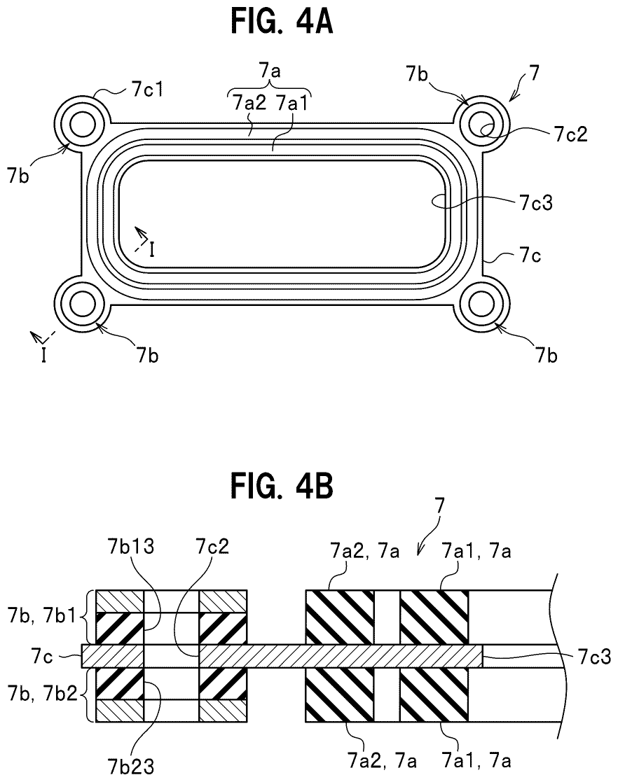

FIG. 4A is a top view of the liquid leakage prevention and anti-vibration component 7. FIG. 4B is a cross section at I-I of FIG. 4A.

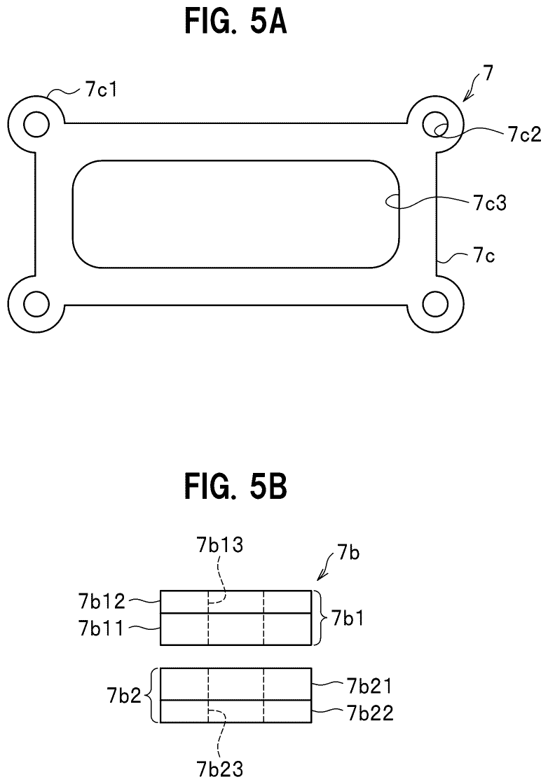

FIG. 5A is a top view of a support plate 7c and FIG. 5B is an exploded side view of the anti-vibration rubber 7b.

As mentioned above, the liquid leakage prevention and anti-vibration component 7 shown in FIG. 4A is a single component (see FIG. 4B) including a double sealing gasket 7a and four anti-vibration rubbers 7b that are vulcanization-bonded to both sides of the support plate 7c that is a single-layer structural material (see FIG. 5A).

The double sealing gasket 7a is a doubly arranged, annular, leak-proof rubber for preventing the cooling liquid r from leaking outside.

The anti-vibration rubber 7b suppresses the vibrations from the vehicle 1 (FIG. 1) from transmitting to the electrical component body 6h.

<Support Plate 7c>

The support plate 7c shown in FIG. 5A consists mainly, for example, of a long rectangular thin metal plate.

The support plate 7c has a circular protrusion 7c1 at each of its four corners. A center of the circular protrusion 7c1 is penetrated with a round hole 7c2.

There is formed in the center of the support plate 7c a large, rectangular elongate hole 7c3 through which the cooling liquid r flows (See FIG. 3). The shape of the elongate hole 7c3 is not limited to rectangular.

The support plate 7c is made by sheet-metal forming using a stainless steel plate or the like with a titanium layer formed on its surface. The support plate 7c may be made of a rust-proofed ordinary steel plate (SS400), general rolling structural steel sheet (SPHC, and the like.), or any other metal sheet other than stainless steel plate.

Or, the support plate 7c can be made of any material other than a metal plate, such as a reinforced plastic plate with glass fiber or carbon fiber, as long as the material satisfies prescribed conditions on strength, rust resistance, weather resistance, aging degradation resistance, and the like.

<Double Sealing Gasket 7a>

The double sealing Gasket 7a shown in FIGS. 4A and 4B is placed respectively on both sides of the support plate 7c. In detail, the double sealing gasket 7a is placed on one side and on the other side of the support plate 7c.

The double sealing gasket 7a includes a first sealing gasket 7a1 and a second sealing gasket 7a2.

The double sealing gasket 7a is vulcanization-bonded to the one side and the other side of the support plate 7c respectively.

As shown in FIG. 4B, the first sealing gasket 7a1 has a rectangular cross section and is annularly formed around the elongate hole 7c3 of the support plate 7c (see FIG. 4A).

The second sealing gasket 7a2 has a rectangular cross section and is annularly formed around and outside the first sealing gasket 7a1.

As described above, the double sealing gasket 7a is doubly formed on the outside of the elongate hole 7c3 of the support plate 7c.

The bolts 5b shown in FIG. 3 are screwed into the female threads 5m of the VCU case 5, and thereby the double sealing gasket 7a placed on the one side and the other side of the support plate 7c is pressed and fixed to the VCU case 5 and the electrical component body 6h. Pressing the double sealing gasket 7a causes it to elastically deform on the one side and the other side of the support plate 7c and to adhere to the VCU case 5 and the electrical component body 6h. The adhesion of the double sealing gasket 7a securely prevents leakage of the cooling liquid r (see FIG. 3).

<Anti-Vibration Rubber 7b>

The anti-vibration rubber 7b shown in FIGS. 4A and 4B dampens and isolates the vibration of the VCU case 5 so that the vibration does not propagate to the electrical component 6.

The anti-vibration rubber 7b includes a first anti-vibration rubber 7b1 and a second anti-vibration rubber 7b2.

The first anti-vibration rubber 7b1 is placed on one side of the support plate 7c, and the second anti-vibration rubber 7b2 is placed on the other side of the support plate 7c.

The first and second anti-vibration rubbers 7b1 and 7b2 have a first center hole 7b13 and a second center hole 7b23 respectively penetrating through their centers, which are approximately the same size as the round hole 7c2 in the circular protrusion 7c1.

The first anti-vibration rubber 7b1 has a rubber portion 7b11 and a washer portion 7b12.

The rubber portion 7b11 is formed of, for example, rubber, which has a vibration damping effect. In detail, the rubber portion 7b11 has a spring constant and internal resistance, and dampens vibration through energy loss and internal friction. The rubber portion 7b11 is made using, for example, natural rubber, butyl rubber, silicone rubber, and the like. Other materials may be used for the rubber portion 7b11 as long as they have a vibration-damping effect and satisfy certain conditions such as abrasion resistance, weather resistance, and aging degradation resistance.

The washer portion 7b12 is mainly made of rust proofed ordinary steel sheet (SS400), structural steel sheet for general rolling (SPHC, etc.), stainless steel plate (SUS), and the like. The washer portion 7b12 may be made of other materials as long as they meet requirements of strength, abrasion resistance, rust resistance, and the like.

The second anti-vibration rubber 762 has a rubber portion 7b21 and a washer portion 7b22.

The rubber portion 7b21 is made of the same material as the rubber portion 7b11 described above.

The washer portion 7b22 is made of the same material as the washer portion 7612 described above.

As mentioned above, the double sealing gasket 7a and anti-vibration rubber 7b (7b1, 7b2) shown in FIGS. 4A and 4B are structured to be vulcanization-bonded respectively to the one side and the other side of the support plate 7c to be integrated into one body.

### Effect of First Embodiment

The above structure shows that the liquid leakage prevention and anti-vibration component 7 is effective in anti-vibration and further in cooling the electrical component 6 by directly contacting the cooling liquid r in the cooling liquid channel 5a (FIG. 3) to the electrical component 6. The liquid leakage prevention and anti-vibration component 7 is easy to manufacture because it is made into a single component by vulcanization-bonding the double sealing gasket 7a and the anti-vibration rubber 7b sandwiching the support plate 7c on its both sides.

Also, assembly is easy because it is completed through handling only one component of the liquid leakage prevention and anti-vibration component 7. This reduces the number of parts and makes production easier. Further, workability in assembling the electrical component 6 is able to be improved. Therefore, a highly productive structure is achieved.

In addition to the anti-vibration effect of the double sealing gasket 7a, the single component of the liquid leakage prevention and anti-vibration component 7 made by sandwiching can suppress deformation of the double sealing gasket 7a due to water pressure, even when cooling the electrical component body 6h through direct contact to the cooling liquid r in the cooling liquid flow channel 5a. In addition, the double surrounding structure of the double sealing gasket 7a shown in FIGS. 4A and 4B allows reliably suppressing leakage of the cooling liquid r with the second sealing gasket 7a2, even if the single first sealing gasket 7al leaks. Therefore, it is possible to improve the quality of the electrical component body 6h shown in FIG. 3, which requires vibration isolation and cooling.

In the first embodiment, the double sealing gasket 7a that is structured with two enclosures is exemplified, but a multi-enclosure sealing gasket structured with three or more enclosures may be also used.

### Second Embodiment

A liquid leakage prevention and anti-vibration component 27 of the second embodiment differs from the liquid leakage prevention and anti-vibration component 7 of the first embodiment, which is integrally fixed, in that the liquid leakage prevention and anti-vibration 27 has a structure to be assembled.

Other components of the liquid leakage prevention and anti-vibration component 27 have the same design as those of the liquid leakage prevention and anti-vibration component 7, and thus identical components are indicated with the numbers in the twenties whose first digit is the same as those of the liquid leakage prevention and anti-vibration component 7, and overlapped explanations are omitted.

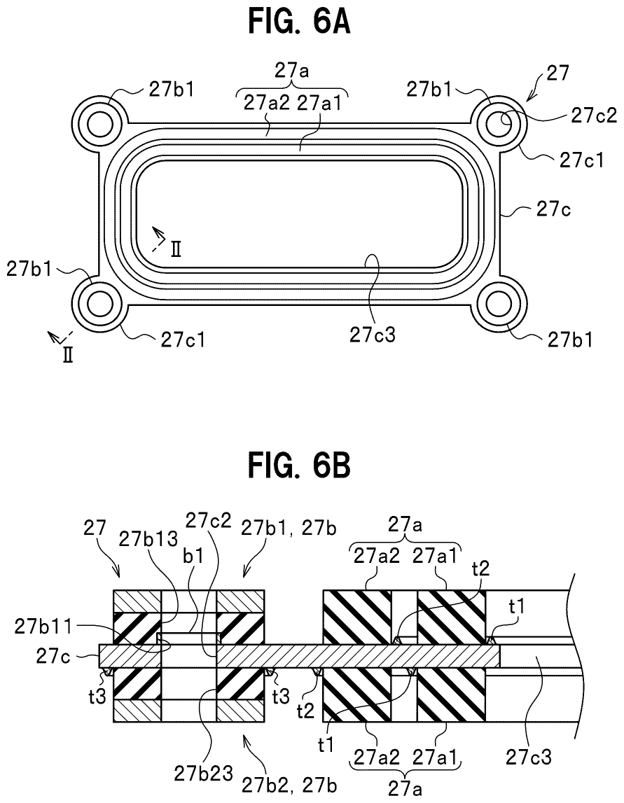

FIG. 6A is a view seen from one side of the liquid leakage prevention and anti-vibration component 27 of the second embodiment. FIG. 6B is a partially enlarged view of the II-II cross-section of FIG. 6A.

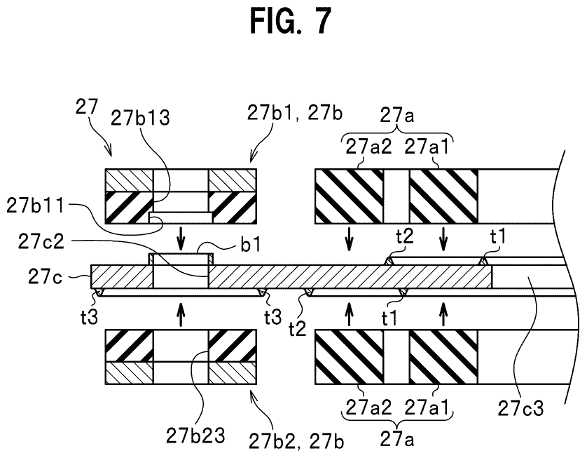

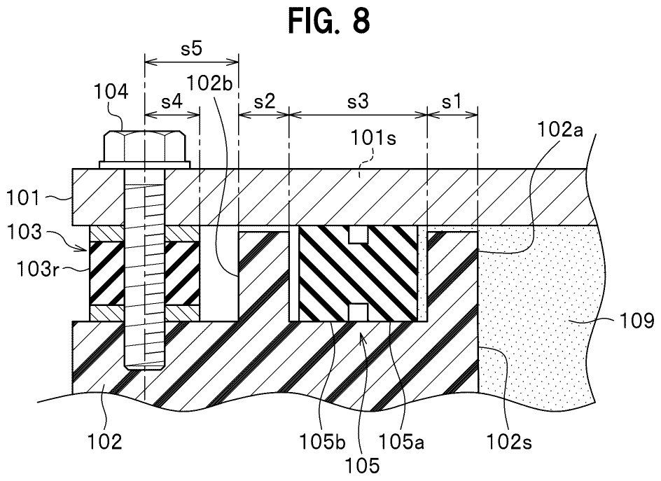

FIG. 7 is a partially enlarged view of the II-II cross-section of FIG. 6A showing a process of assembling the liquid leakage prevention and anti-vibration component 27.

On one side and the other side of the support plate 27c of the second embodiment shown in FIGS. 6A and 6B, there are arranged two of double sealing gaskets 27a, in an annularly continuous manner of doubly surrounding a central elongate hole 27c3.

In detail, the support plate 27c has an annular first sealing gasket 27a1 on the one side around the central elongate hole 27c3. Here, on the one side of the support plate 27c, a plurality of protrusions t1 (see FIG. 6B) for a first positioning of the first sealing gasket 27a1 are formed by drawing. The protrusions t1 for the first positioning are used to facilitate positioning of the first sealing gasket 27a1 on the support plate 27c.

The second sealing gasket 27a2, which is formed in a continuous annular form, is located outside the first sealing gasket 27a1 on the support plate 27c. Here, on the one side of the support plate 27c, there are multiple protrusions t2 for a second positioning of the second sealing gaskets 27a2 (see FIG. 6B) formed by drawing. The protrusions t2 allows the second gasket 27a2 to be easily positioned on the support plate 27c.

Similarly, an annular first sealing gasket 27a1 and an annular second sealing gasket 27a2 are arranged in a manner of surrounding the elongate hole 27c3 on the other side of the support plate 27c.

The first sealing gasket 27a1 is positioned on the support plate 27c by the first positioning protrusion t1 formed on the other side of the support plate 27c. The second sealing gasket 27a2 is positioned on the support plate 27c by the projection t2 formed on the other side of the support plate 27c for the second positioning.

The support plate 27c shown in FIG. 6A has a circular protrusion 27c1 in each of the four corners, and a round hole 27c2 penetrating through the center of the circular protrusion 27c1.

A first anti-vibration rubber 27b1 is provided on one side of the circular protrusion 27c1.

A second anti-vibration rubber 27b2 is provided on the other side of the 27c1.

The first anti-vibration rubber 27b1 has a first center hole 27b13 in the center.

The second anti-vibration rubber 27b2 has a second center hole 27b23 in the center.

As shown in FIG. 6B, on one side of the support plate 27c, the first anti-vibration rubber 27b1 is placed so that the first center hole 27b13 is substantially aligned with the round hole 27c2 in the support plate 27c. Here, on the one side of the four circular protruding portions 27cl, a first anti-vibration rubber positioning protrusion b1 is formed by burring or drawing. Note that the first anti-vibration rubber 27b1 has an escape portion 27b11 (see FIGS. 6B and 7) recessed for the first anti-vibration rubber positioning protrusion b1 (see FIGS. 6B and 7). As a result, the first anti-vibration rubber positioning protrusion b1 is formed outside of the bolt 5b (see FIG. 3) so that the first anti-vibration rubber positioning protrusion b1 does not get in a way of the bolt 5b. As shown in FIGS. 6B and 7, the first anti-vibration rubber positioning protrusion b1 allows easy installation of the four first anti-vibration rubbers 27b1 on the one side of the support plate 27c.

Similarly, on the other side of the support plate 27c, the second anti-vibration rubber 27b2 is disposed so that the second center hole 27b23 is substantially aligned with the round hole 27c2 of the support plate 27c. Here, on the other side of the four circular protruding portions 27cl, a second anti-vibration rubber positioning protrusion t3 for the second anti-vibration rubber 27b2 is formed by burring or drawing. As shown in FIGS. 6B and 7, the second anti-vibration rubber positioning protrusions t3 facilitate installation of the four second anti-vibrations 27b2 on the other side of the support plate 27c. FIGS. 6B and 7 show a case in which the first anti-vibration rubber 27b1 is positioned by the first anti-vibration rubber positioning protrusion b1 made by the burring, and a case in which the second anti-vibration rubber 27b2 is positioned by the second anti-vibration rubber positioning protrusion t3 made by the drawing.

The first anti-vibration 27b1 and the second anti-vibration 27b2 both may be positioned by the positioning protrusions made by the drawing, or by positioning protrusions made by the burring, and the form of components for positioning may be selected arbitrarily.

### <Applications of Industrial Adhesive and Industrial Double-Coated Adhesive Tape>

The double sealing gasket 27a may be fixed on the one side and the other of the support plate 27c by applying industrial adhesive or industrial double-sided tape on an attachment surface of the double sealing gasket 27a onto the support plate 27c and/or an attachment surface of the support plate 27c onto the double sealing gasket 27a.

Similarly, the first anti-vibration rubber 27b1 and the second anti-vibration rubber 27b2 may be fixed on the one side and the other side of the support plate 27c by applying industrial adhesive (simply adhesive) or industrial double-sided tape (simply double-sided tape) on the attachment surfaces of the first and second anti-vibration rubbers 27b1 and 27b2 onto the support plate 27c and/or the attachment surfaces of the support plate 27c onto the first and second anti-vibration rubbers 27b1 and 27b2. If the industrial adhesive (simply adhesive) or industrial double-sided tape (simply double-sided tape) is applied, the double sealing gasket 27a and the first and second anti-vibration rubbers 27b1 and 27b2 are securely fixed onto the support plate 27c. This facilitates assembly and improves workability.

### Effect of Second Embodiment

As described above, similarly to the first embodiment, the liquid leakage prevention and anti-vibration component 27 causes the anti-vibration effect and further the effect of suppressing leakage of the cooling liquid r even when cooling the electrical component 6h by making it directly contact with the cooling liquid r in the cooling liquid channel (see FIG. 3). In addition, the liquid leakage prevention and anti-vibration component 27 allows assembly to be completed by only assembling the liquid leakage prevention and anti-vibration component 27, which makes assembly easy and improves workability.

In further addition to the anti-vibration effect by the double sealing gasket 27a, even when cooling the electrical component body 6h by making it directly contact with the cooling liquid r in the cooling liquid channel 5a (see FIG. 3), the liquid leakage prevention and anti-vibration component 27 prevents the double sealing gasket 27a from being deformed by water pressure by sandwiching the support plate 27c. In further addition, the double sealing gasket 27a shown in FIGS. 6A and 6B is structured in the double-structure, which can reliably suppress leakage of the cooling liquid.

### OTHER EMBODIMENTS

1) The above embodiments describe the cases in which the electrical component 6 is applied to the vehicle 1, but it can be effectively applied to any machinery other than the vehicle 1, such as ships, heavy machinery, machine tools, general machinery, airplanes, flying vehicles, and the like.
2) This invention is not limited to the configurations of the first and second embodiments described above, but various modifications and detailed variations from the above two embodiments are available within the scope of the appended claims.

### REFERENCE SIGNS LIST

5: VCU case (housing)
5a: Cooling liquid channel
6: Electrical component
6a: Bottom of electrical component body
6a1: Surface that forms a flat shape
6h: Electrical component body
6k: First through-hole
6s: Electric element
7a: Double sealing gasket (gasket)
7b1: First anti-vibration rubber (anti-vibration rubber)
7b13: First center hole (third through-hole)
7b2: Second anti-vibration rubber (anti-vibration rubber)
7b23: Second center hole (third through-hole)
7c: Support plate (plate)
7c2: Round hole (Second through-hole)
7c3: Elongate hole (cooling hole)
r: Cooling liquid

1. An electrical component comprising:
an electrical component body that houses therein an electrical element and is provided with a first through-hole for fixing;
a plate that is provided with a second through-hole arranged facing the first through-hole and a cooling hole through which cooling liquid flows;
anti-vibration rubbers arranged on one side and other side of the plate while surrounding the second through-hole of the plate and each having a third through-hole facing the second through-hole, and
gaskets arranged twice or more times surrounding the cooling hole respectively on the one side and the other side of the plate,
wherein
the electrical component body, the plate, the anti-vibration rubbers, and the gaskets are fixed to a housing, and
the electrical component body has a bottom surface at least a part of which is contact with the cooling liquid flowing through a cooling liquid channel of the housing.

2. The electrical component according to claim 1,
wherein
the first through-hole is provided at a place that forms a flat surface on the bottom surface of the electrical component body.

3. The electrical component according to claim 1,
wherein
the anti-vibration rubber and the gaskets are fixed to the plate and structured as a single unit.

4. The electrical component according to claim 3,
wherein
the anti-vibration rubber and the gasket are vulcanization-bonded to the plate.

5. The electrical component according to claim 3,
wherein
the anti-vibration rubber and the gasket are attached to the plate through adhesive or double-sided tape.
